(19) United States
(12) Patent Application Publication
(10) Pub. No.: US 2016/0332301 A1
(43) Pub. Date: Nov. 17, 2016

(54) METHOD OF HANDLING AND TRANSPORTING FLAT OBJECTS BETWEEN A PLURALITY OF FLAT OBJECT POCESSING UNITS AT ROBOTIC STATION

(71) Applicant: Boris Kesil, Santa Clara, CA (US)

(72) Inventor: Boris Kesil, Santa Clara, CA (US)

(21) Appl. No.: 14/711,753

(22) Filed: May 13, 2015

(51) Int. Cl. B25J 9/16; H01L 21/687; G01G 17/00; G01B 21/08; G01B 21/32; B25J 9/00; H01L 21/677

(52) U.S. Cl. CPC B25J 9/1682; B25J 9/009; H01L 21/68707; H01L 21/67778; G01B 21/08; G01B 21/32; G01G 17/00

(57) ABSTRACT

Proposed is a method of handling and transporting flat objects such as semiconductor wafers or wafer substrates on a robotic station by means of a robot assembly equipped with a dual-gripper end effector. Since the end effector has two independently operating flat-object grippers which are arranged at an angle, e.g., of 90° to each other and which are rotatable simultaneously around a common axis of rotation, it becomes possible to hold two flat objects alternatively in two different planes and to exclude a big swing of the robot arm in the same plane. This allows manipulation with the flat objects in a small space. While one of the objects is being placed into a processing unit by one of the grippers, another wafer is held in a waiting position by the second gripper so that after the first wafer is loaded into an appropriate unit, the second wafer can be quickly turned into the working position and the first gripper into the waiting position.

### FIELD OF THE INVENTION

The present invention relates to a method of handling and transporting objects on a robotic station, in particular to a method of transferring objects, such as semiconductor wafers, between a plurality of object positions on a robotic station. More specifically, the invention relates to a method of handling and transporting objects, such as semiconductor wafers, between object positions on a robotic station by means of a robot assembly equipped with a dual-gripper end effector.

### DESCRIPTION OF THE PRIOR ART

In some places of the description flat objects are referred to as “semiconductor wafers”. It is understood, however, that the method of the invention is not limited to handling semiconductor wafers or wafer substrates and that flat objects are not necessarily of a round shape. Moreover, the objects are not necessarily flat. For convenience of the description reference will be made to semiconductor wafers.

At the present time, wafer grasping, handling, sorting and loading/unloading operations are carried out by means of mechanically operated and numerically controlled robots. Such a robot is normally provided with a robot arm that handles wafers with so-called end effectors.

Examples of robot arms used, e.g., in the semiconductor industry for handling, transporting, and sorting semiconductor wafers, wafer substrates, or other flat objects are described in a number of publications, e.g., in U.S. Pat. No. 6,601,468 issued on Aug. 5, 2003 to G. Grover, et al. This patent discloses a robot drive assembly for moving a working tool in x, y, z and theta directions on a robotic station and comprises three independent, coaxially nested tubes, each tube being driven around a common central axis by drive belts attached to separate drive motors located in a mounting flange associated with the outermost tube. The motors, and the tubes which they drive, provide horizontal rotary motion to a robot arm attached to the upper end of the outer tube and the wrist and elbow of that arm. A fourth motor controls vertical motion of the whole assembly. The robot system also includes motor position adjustment structure and belt tension structure designed for ease of use and to eliminate movement of tensioned components once locked in position.

The robot arm of this assembly together with its end effector performs object manipulation movements in the same horizontal plane which requires a large space for the robot arm swing

In another example, e.g., US Patent Application Publication No. 20050217053 published on Oct. 6, 2005 (inventors: Kim Kid-sang, et al.), disclosure is given to a robot arm mechanism that includes a housing, upper and lower arms rotatably mounted on the housing, a respective substrate-supporting blade connected to each upper arm, and first, second, third and fourth driving units for rotating the housing, the upper and lower arms and the blade independently of one another. Thus, positions of the blades are readily controlled so that the blades and/or the substrates supported by the blades can be prevented from colliding against the inner wall of the chambers into and from which the substrates are transferred by the robot arm mechanism. Each arm operates in the same horizontal plane and therefore has the same drawback as the mechanical arm disclosed in U.S. Pat. No. 6,601,468.

In robotics, an end effector is a device or tool connected to the end of a robot arm. For handling semiconductor wafers, an end effector may be made in the form of grippers of the types described in a number of patent publications.

Known in the art is also the use of dual-gripper end effectors on robot assemblies for handling, transporting and/or sorting semiconductor wafers. For example US Patent Application Publication No. 20140294551 published on Oct. 2, 2014 (inventors: C. Hofmeister, et al. discloses a substrate transport apparatus with multiple movable arms utilizing a mechanical switch mechanism. The apparatus uses a single and dual-gripper end effector, multiple link robot arm systems having triaxial drive motors described in U.S. Pat. 6,105,454 issued on Aug. 22, 2000 to Paul Bacci, et al. Each of two embodiments includes two end effectors or hands. A first embodiment comprises two multiple link robot arm mechanisms mounted on a torso link that is capable of 360 degree rotation about a central axis. Each robot arm mechanism includes an end effector having a single hand. A second embodiment has only one of the robot arm mechanisms and has an end effector with two oppositely extending hands. Each robot arm mechanism uses two motors capable of synchronized operation to permit movement of the robot arm hand along a curvilinear path as the extension of the hand changes. A third motor rotates the torso link about the central axis and permits rotation of the torso link independent of the motion of the robot arm mechanism or mechanisms mounted to it. The presence of the rotatable torso link together with the independent robot arm motion provides a high speed, high throughput robot arm system that operates in a compact work space.

Each of two embodiments includes two end effectors or hands. A first embodiment comprises two multiple link robot arm mechanisms mounted on a torso link that is capable of 360 degree rotation about a central axis. Each robot arm mechanism includes an end effector having a single hand. A second embodiment has only one of the robot arm mechanisms and has an end effector with two oppositely extending hands. Each robot arm mechanism uses two motors capable of synchronized operation to permit movement of the robot arm hand along a curvilinear path as the extension of the hand changes. A third motor rotates the torso link about the central axis and permits rotation of the torso link independent of the motion of the robot arm mechanism or mechanisms mounted to it. The presence of the rotatable torso link together with the independent robot arm motion provides a high speed, high throughput robot arm system that operates in a compact work space.

### SUMMARY OF THE INVENTION

The invention relates to a method of handling and transporting flat objects, such as, e.g., semiconductor wafers, between object positions on a robotic station by means of a six axis robot assembly equipped with a dual-gripper end effector.

The method of the invention comprises the following steps: providing a robotic station equipped with at least three object processing positions and with a six axis robot assembly having six axes of rotation and a dual-gripper end effector comprising a least two independently operating flat-object grippers arranged at an angle to each other and jointly rotatable around one of the axes of the six-axis robot assembly between a first position in which one flat object is held by one of the two independently operating flat object gripping/releasing mechanisms in a position for placing this one object into one of the flat object processing units and a second position in which a second object is held by a second of the two independently operating object gripping/releasing mechanisms in a waiting position for placing the second object into one of the flat object processing units; and transferring the end effector between the flat object processing units for placing the object held in one or both mechanisms selectively to any of the flat object processing units by selectively turning the end effector to the first or the second position.

Since the end effector used in the method of the invention has two independently operating flat-object grippers arranged at an angle, e.g., of 90° to each other, and rotatable simultaneously around a common axis of rotation, it becomes possible to hold two flat objects alternatively in two different planes and to exclude a big swing of the robot arm in the same plane. This allows manipulation with the flat objects, such as, e.g., semiconductor wafers, in a small space. While one of the semiconductor wafers is being placed into a wafer processing unit by one of the grippers, another wafer is held in a waiting position by the second gripper so that after the first wafer is loaded into an appropriate unit, the second wafer can be quickly turned into the working position and the first gripper into the waiting position.

According to another aspect of the invention, the method may be carried out by providing the robotic station with the two or more additional storage units and to sort the wafers checked in the wafer checking station for storing in different storage units depending on the results of wafer checking operation. For example, the checking operation may comprise weighing and the wafer can be sorted in different storage units by weight. Alternatively, the checking operation may comprise measurement of wafer thickness, wafer warping, etc.

### BRIEF DESCRIPTION OF THE DRAWINGS

FIG. 1 is a plan view of an exemplary multi-positional robotic station suitable for carrying out the method of the invention. FIG. 2 is a three-dimensional view of a six axis robot assembly suitable for the method. FIG. 3a is a rear view of the dual-gripper end effector, and FIG. 3b is a front view of the end effector of the six axis robot assembly of FIG. 2.

FIG. 4 is a three-dimensional view of the dual-gripper end effector of FIGS. 3a and 3b holding one semiconductor wafer in one flat-object gripper.

FIG. 5 is a three-dimensional view of the dual-gripper end effector of FIGS. 3a and 3b holding a semiconductor wafer in each flat-object gripper.

### DETAILED DESCRIPTION OF THE INVENTION

The present invention relates to a method of handling and transporting flat objects on a robotic station, in particular to a method of transferring flat objects, such as semiconductor wafers or wafer substrates between a plurality of wafer positions on a robotic station.

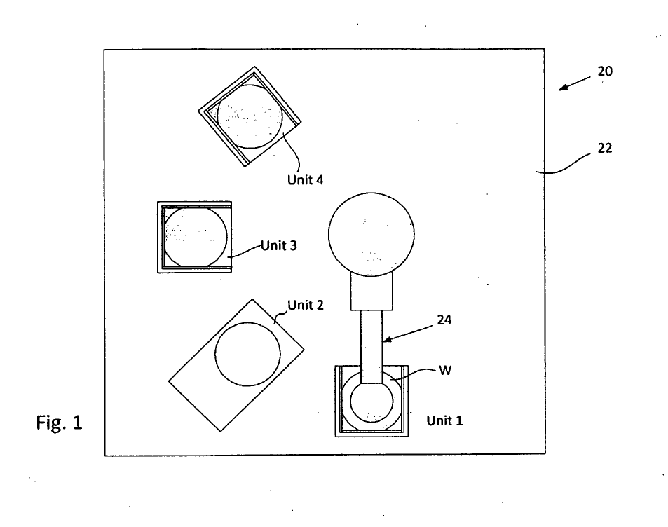

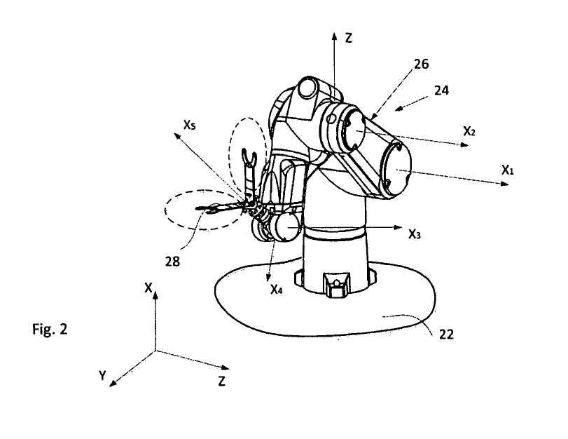

FIG. 1 is a plan view of an exemplary robotic station 20 suitable for carrying out the method of the invention. This robotic station constitutes an object of another U.S. patent application Ser. No. ______ of the same application (filed on ______) which is now pending. The robotic station 20 comprises a support base 22 which support a plurality of wafer processing and/or storage units between which a wafer has to be transferred by means of a robot arm equipped with an end effector having a flat-object gripper for loading and unloading flat objects, e.g., semiconductor wafers or wafer substrates.

In more detail the 6-axis robot assembly 24 is shown in FIG. 2 which is a three-dimensional view of the assembly. An example of such a 6-axis robot assembly is shown in US Patent Application Publication No. 20060035563 published on Feb. 16, 2006 (invetors: Kalenian; William J. ; et al.). This publication describes methods and systems for use in processing objects such as wafers, including polishing and/or grinding wafers.

This robot assembly 24 has a mechanical arm 26 with an end effector 28 on the free end. A construction of this six axis robot assembly makes it possible for the end effector 28 to perform movements around six axes, five of which are needed for carrying out the method of the invention. These movements are rotations around axes X1, X2, X3, X4, X5 and Z shown in FIG. 1. More specifically, these movements allows the end effector 28 to execute any translator and rotational movements with the boundaries of the wafer positions shown in FIG. 1, where a Unit 1 is a wafer FOUP or storage position; Unit 2 is, e.g., a wafer sorter, reader, or another wafer processing position; Unit 3 is a second storage position; and Unit 4 is a second storage position.

The end effector 28 is a so-called dual-blade end effector that may have a mechanical or a vacuum wafer holder and have two independently and alternatively operating grippers or holders.

The dual-gripper end effector 28 suitable for the method of the invention is shown in the drawings, where FIG. 3(a) is a back view and FIG. 3(b) is a front view of the end effector 28. It can be seen that the individual flat-object grippers are arranged at an angle of 90° to each other and that they can alternatively be turned in working position by rotating around the axis X5.

However, the conventional dual-blade end effectors perform wafer transfer operations in one plane and therefore require a large space or swinging the robot arm between various working positions (see U.S. Pat. No. 6,105,454). The 6-axis robot used herein for realization of the method, makes it possible to use each individual gripper of the dual-blade end effector in different planes due to rotation of the end effector around axis X5 shown in FIG. 2, whereby in accordance with the method of the invention the dual-gripper wafer transfer operations can operate in a much smaller space.

Having considered an example of a robotic station architecture and freedom of movements of the end effector 28, let us now consider an example of the method of the invention that can be carried out on a robotic station of FIG. 1.

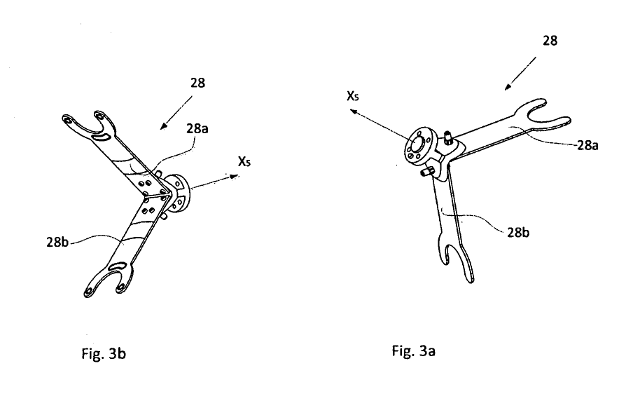

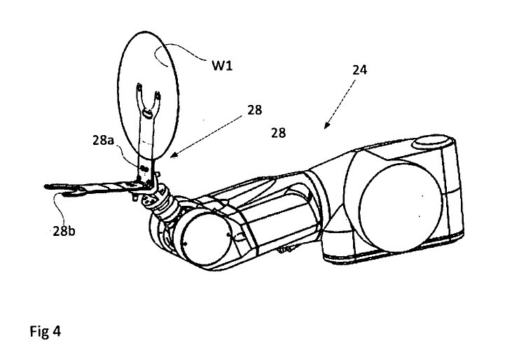

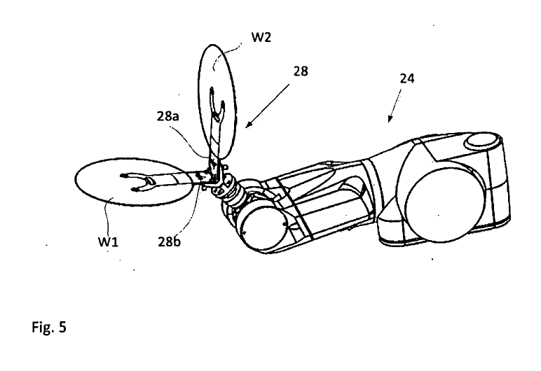

Let us assume that the dual-blade end effector 28 is located on the Unit 1 or FOUP that stores unprocessed flat objects (not shown) and that the robot has just started the wafer processing operation and therefore the end effector initially holds only one unprocessed flat object, e.g., a semiconductor wafer W, in one of its grippers of the dual-gripper mechanism. This is shown in FIG. 4 a part of the robot arm 24 with a wafer W1 is held by a vacuum-suction force in the flat-object gripper 28a. It is understood that prior to the position shown In FIG. 4, the end effector 28 should pick up the unprocessed flat object, e.g., an unprocessed semiconductor wafer W1 from the stack in the FOUP, raise it and turn by 90° to the position of FIG. 5. It was possible due to freedom of movements described above.

Next, by rotating the mechanical arm with six axes of rotation around the axis Z (FIG. 2), the wafer W1 is transferred to the Unit 2 into which the wafer W1 is placed for testing or processing by rotating around and moving along appropriate axes. The Unit 2 station may have such functions as a notch-orientation function, weighing, thickness measurement, warping and bow control, etc. Now, both flat-object grippers are free of the wafers. Immediately after getting rid of the wafer W1, the end effector 28 returns to the working position of the Unit 1, then moves away from the Unit 1 to allow the turn around the axis X5 for placing the first or the second flat-object gripper into the wafer pick up position for descending and picking up the second wafer W2. However, the turn around the axis X5 may occur during movement from Unit 2 to Unit 1. Now the end effector again has only one but the second wafer W2, while the first wafer W1 is being processed on the Unit 1. After the flat-object gripper picks up the second wafer W2, it return to Unit 2, places the empty flat-object gripper (let us assume that it is again the first gripper 28b) into a position for picking up the first wafer W1 from the Unit 2. This is performed by using respective freedoms of movements provided by the six-axis robot. Thus, the flat-object gripper 28b now has the first wafer W1 in the flat-object gripper 28, while the second flat-object gripper 28a holds the second wafer W2. This is shown in FIG. 5, which is a view similar to FIG. 4 but in different positions of the flat-object grippers. Next, depending on the results of the processing, the end effector 28 transfers the treated wafer W1 to the Unit 3 or to the Unit 4. For the example, depending on the checking results the wafers can be sorted between two storage units, i.e., the Units 3 and 4, by weight, by thickness, etc. Next, the end effector 28 places the second wafer W2 into the now-empty Unit 2, then returns to the Unit 1, and the cycle is repeated.

According to another aspect of the invention, the end effector 28 may initially pick up two semiconductor wafers from the FOUP. In other words, the end effector 28 picks up a first semiconductor wafer W1 from FOUP with the first flat/object gripper 28a. The end effector 28 is then moves away from the FOUP, flat-object grippers are turned to a position turn into a position prepared for picking up the second wafer W2 by the second flat-object gripper 28b, and then the end effector 28 moves to the FOUP and picks up the second semiconductor wafer W2 with the second flat-object gripper 28b. The robot arm 24 then moves to the Unit 2 for checking first the first wafer W1 (or the second wafer W2) with regard to flat object characteristics, i.e., characteristics of the wafers to be tested, e.g., for weighing or measuring. The selected wafer is checked or tested, the results of the test or checking are recorded, and then the processed wafer is picked up by the same flat-object gripper 28a or 28b (depending on which one was used for loading the wafer to the checking Unit 2) and is placed into the Unit 3 for storage. The checking unit is used for checking the wafer parameters, e.g., for measuring the thickness or warping of the wafer, and for producing the checking results. The end effector returns to Unit 2, turns to a position for loading the non-processed wafer W2 (or W1, if the wafer W2 was one processed on the preceding operation). The end effector is waiting for the completion of testing or checking of the wafer currently located in the Unit 2. Then the second processed wafer W2 (or W1) is placed into the storage Unit 3, the end effector 28 with now empty flat-object grippers 28a and 28b returns to the FOUP, and the process is repeated.

Similarly to the first example, depending on the results of tests or checking, the wafers processed on the Unit 2 may be sorted between the storage Units 3 and 4. It is understood that one or two storage units are shown only as an example, and the number of the storage units may be greater that two.

The method of the invention has been shown and described with reference to specific examples. It is understood, however, that these examples do not limit the scope of application of the invention and that any changes and modifications are possible without deviations from the scope of the attached patent claims. For example, flat objects are not necessarily semiconductor wafers or wafer substrate, and may comprise flat objects of a non-circular shape. The objects are not necessarily flat and may comprise small or delicate parts of any three-dimensional configuration. The object grippers are shown as vacuum suction type grippers but mechanical grippers can be used instead.

1. A method of handling and transporting flat objects between a plurality of flat object processing units on a robotic station, the method comprising:
providing a robotic station with at least three flat object processing units and with a six axis robot assembly having mechanical arm with six axes of rotation and a dual-gripper end effector comprising at least two independently operating flat-object grippers arranged at an angle to each other and jointly rotatable around one of the axes of the six-axis robot assembly between a first position in which one flat object is held by one of the two independently operating flat-object grippers in a position for placing this one flat object into one of the flat object processing units and a second position in which a second flat object is held by a second of the two independently operating flat-object grippers in a waiting position for placing the second flat object into one of the flat object processing units; and transferring the end effector between the flat object processing units for placing the flat object held in one of the flat-object grippers or flat objects held in both flat-object grippers selectively to any of the flat object processing units by selectively turning the end effector to the first or the second position.

2. The method of claim 1, wherein the flat objects are selected from the group consisting of semiconductor wafers and semiconductor wafer substrates and wherein one of the flat object processing units is a FOUP that stores unprocessed flat objects, one of the flat object processing units is a flat object checking unit that produces checking results, and one of the flat object processing stations is a first flat object storage unit.

3. The method of claim 2, further comprising the step of providing the robotic station with at least a second flat object storage unit for sorting the flat objects between the first flat object storage unit and the second flat object storage unit depending on the checking results on the flat object checking unit.

4. The method according to claim 2, wherein the angle at which flat-object grippers are arranged to each other is 90°.

5. The method according to claim 3, wherein the angle at which flat-object grippers are arranged to each other is 90°.

6. The method according to claim 4, wherein checking of the flat objects on the flat object checking unit is measuring the flat object characteristics.

7. The method according to claim 5, wherein checking of the flat objects on the flat object checking unit is measuring the flat object characteristics.

8. A method of handling and transporting flat objects between a plurality of flat object processing units on a robotic station, the method comprising:
a) providing a robotic station having a plurality of flat object processing units with a six axis robor assembly having a mechanical arm with a dual-blade end effector with two independently operating flat object gripping/releasing mechanisms arranged at an angle to each other and jointly rotatable between a first position in which one flat object is held in one of the two independently operating flat object gripping/releasing mechanisms in a position for placing said one flat object into one of said flat object processing units and a second position in which a second flat object is held by a second of the two independently operating flat object gripping/releasing mechanisms in a waiting position for placing said second flat object into one of said flat object processing units;
b) using at least one of the flat object processing units of said plurality as a FOUP for flat objects to be processed, using at least a second of the flat object processing units of said plurality as a flat object checking unit, and using a third of the flat object processing units of said plurality as a flat object storage unit;
c) placing the dual-blade end effector into a position for taking a first flat object from the FOUP with one of the two independently operating flat object gripping/releasing mechanisms;
d) taking the first flat object from the FOUP with one of the two independently operating flat object gripping/releasing mechanisms;
e) transferring the dual-blade end effector with the first flat object held by said one of the two independently operating flat object gripping/releasing mechanisms to the flat object checking units and placing the first flat object into the flat object checking unit;
f) processing the first flat object in the flat object checking units;
g) transferring the dual-blade end effector to the FOUP;
h) placing one of the two independently operating flat object gripping/releasing mechanisms into a position for taking a second flat object from the FOUP, while the first flat object is being processed in the flat object checking unit;
i) taking the second flat object from the FOUP with said one of the two independently operating flat object gripping/releasing mechanisms;
j) transferring the dual-blade end effector to the flat object testing unit;
k) taking the first flat object from the flat object checking position by the second of said two independently operating flat object gripping/releasing mechanisms;
l) transferring the dual-blade end effector to the flat object storing unit;
m) placing the second of said two independently operating flat object gripping/releasing mechanisms into a position for placing the first flat object to the flat object storage position;
n) placing the first flat object to the flat object storing unit from the second of said two independently operating flat object gripping/releasing mechanisms;
o) returning the dual-blade end effector to the flat object checking unit;
p) placing the first of said two independently operating flat object gripping/releasing mechanisms into a position for placing the second flat object into the flat object checking unit;
q) placing the second flat object into the flat object checking unit from the first of said two independently operating flat object gripping/releasing mechanisms;
r) transferring the dual-blade end effector to the FOUP to a position for taking a third flat object with one of the two independently operating flat object gripping/releasing mechanisms; and
s) repeating the steps from c) to r) for the second flat object and the third flat object and so on for the next flat object located in the FOUP and the preceding flat object located in the flat object checking unit.

9. The method of claim 8, wherein the flat objects are selected from the group consisting of semiconductor wafers and semiconductor wafer substrates.

10. The method of claim 9, further comprising the step of providing the robotic station with at least a second flat object storage unit for sorting the flat objects between the first flat object storage unit and the second flat object storage unit depending on the checking results on the flat object checking unit.

11. The method according to claim 9, wherein the angle at which flat-object grippers are arranged to each other is 90°.

12. The method according to claim 10, wherein the angle at which flat-object grippers are arranged to each other is 90°.

13. The method according to claim 11, wherein checking of the flat objects on the flat object checking unit is measuring the flat object characteristics.

14. The method according to claim 12, wherein checking of the flat objects on the flat object checking unit is measuring the flat object characteristics.

15. A method of handling and transporting flat objects between a plurality of flat object processing units on a robotic station, the method comprising:
a) providing a robotic station having a plurality of flat object processing units with a six axis robot assembly having a mechanical arm with a dual-blade end effector with two independently operating flat object gripping/releasing mechanisms arranged at an angle to each other and jointly rotatable between a first position in which one flat object is held in one of the two independently operating flat object gripping/releasing mechanisms in a position for placing said one flat object into one of said flat object processing units and a second position in which a second flat object is held by a second of the two independently operating flat object gripping/releasing mechanisms in a waiting position for placing said second flat object into one of said flat object processing units;
b) using at least one of the flat object processing units of said plurality as a FOUP for flat objects to be processed, using at least a second of the flat object processing units of said plurality as a flat object checking unit, and using a third of the flat object processing units of said plurality as a first flat object storage unit;
c) placing the dual-blade end effector into a position for taking a first flat object from the FOUP with one of the two independently operating flat object gripping/releasing mechanisms;
d) taking the first flat object from the FOUP with one of the two independently operating flat object gripping/releasing mechanisms;
e) moving the end effector away from the FOUP and turning the end effector to a position in which the first flat second flat object gripping/releasing mechanisms assumes a position for gripping the second flat object from the FOUP;
f) gripping the second flat object from the FOUP with the second flat object gripping/releasing mechanisms;
g) transferring the dual-blade end effector with the first flat object and the second flat object to the flat object checking unit;
h) placing the first flat object to the flat object checking unit;
i) checking the first flat object on the flat object checking unit and producing the checking results;
j) taking the first flat object from the flat object checking unit with the first flat object gripping/releasing mechanism;
k) transferring the first flat object to the flat object storage unit;
l) transferring the end effector to the flat object checking unit;
m) placing the second flat object to the flat object checking unit;
n) checking the second flat object on the flat object checking unit and producing the checking results;
o) taking the second flat object from the flat object checking unit;
p) transferring the second flat object from the flat object checking unit;
q) placing the second flat object to the flat object storage unit;
r) returning the end effect to the FOUP; and
s) repeating the steps from c) to r).

16. The method of claim 15, wherein the flat objects are selected from the group consisting of semiconductor wafers and semiconductor wafer substrates.

17. The method of claim 15, further comprising the step of providing the robotic station with at least a second flat object storage unit for sorting the flat objects between the first flat object storage unit and the second flat object storage unit depending on the checking results on the flat object checking unit.

18. The method according to claim 16, wherein the angle at which flat-object grippers are arranged to each other is 90°.

19. The method according to claim 17, wherein the angle at which flat-object grippers are arranged to each other is 90°.

20. The method according to claim 18, wherein checking of the flat objects on the flat object checking unit is measuring the flat object characteristics.

21. The method according to claim 19, wherein checking of the flat objects on the flat object checking unit is measuring the flat object characteristics.
